(19) United States
(12) Patent Application Publication
(10) Pub. No.: US 2007/0140399 A1
(43) Pub. Date: Jun. 21, 2007

(54) Phase-locked loop

(75) Inventors: Marcel A. Kossel, Zurich (CH); Thomas A. Morf, Einsiedein (CH)

Correspondence Address: IBM CORPORATION, T.J. WATSON RESEARCH CENTER, P.O. BOX 218, YORKTOWN HEIGHTS, NY, 10598, US

(73) Assignee: International Business Machines Corporation, Armonk, NY (US)

(21) Appl. No.: 11/403,665

(22) Filed: Apr. 13, 2006

(30) Foreign Application Priority Data
Dec. 20, 2005 (EP) 05112511.0

(51) Int. Cl. H03D 3/24

(52) U.S. Cl. 375/376

(57) ABSTRACT

The phase-locked loop according to the invention comprises a frequency acquisition loop. The frequency acquisition loop comprises a counter that is operable to count the number of periods of an oscillator signal occurring during a predetermined period of time that is derived from a reference signal period of a reference signal. The oscillator signal has an oscillator signal frequency and an oscillator signal phase. The frequency acquisition loop also comprises a subtractor that is operable to compare the counted number of periods with a desired division factor, wherein N=f_{VCOlocked}/f_{ref} and wherein f_{VCOlocked} denotes a desired frequency of the oscillator signal in a locked state of the phase-locked loop and f_{ref} denotes the frequency of said reference signal. The comparison results in a subtractor output frequency value. The phase-locked loop further comprises a phase acquisition loop. The phase acquisition loop comprises a phase rotator for adjusting the oscillator signal by a rotator phase, and a counter that is operable to count the number of periods of the phase-adjusted oscillator signal occurring during the predetermined period of time. The phase acquisition loop also comprises a subtractor that is operable to compare the counted number of periods with the desired division factor. The comparison results in a subtractor output phase value. The phase-locked loop further comprises a state machine that is operable to effectuate in dependence of the subtractor output frequency value and the subtractor output phase value an adjustment of the oscillator signal frequency and the oscillator signal phase.

This invention was made with Government support under Contract No.: H98230-04-C-0920 awarded by the National Security Agency. The Government has certain rights in this invention.

### TECHNICAL FIELD

The present invention relates to a phase-locked loop (PLL) which can be used for example in a serial link receiver.

### BACKGROUND OF THE INVENTION

In M. Kossel, T. Morf, W. Baumberger, A. Biber, C. Menolfi, T. Toifl, M. Schmatz, “A multiphase PLL for 10 Gb/s Links in SOI CMOS Technology,” Digest of 2004 IEEE RFIC Symp., pp. 207-210, June 2004, a multiphase PLL for a serial link receiver at 10 Gb/s is described, that is implemented in a 90 nm CMOS process. The clock generation is based on a dual PLL concept consisting of a narrowband LC tank based PLL (=intermediate frequency or IF PLL) and a wideband PLL that uses a multiphase ring oscillator (=radio frequency or RF PLL). This dual PLL concept helps reduce phase jitter. Owing to the high data speed a static frequency divider with a fixed division ratio N is used in the multiphase RF PLL. This effectuates that the center frequency of the IF PLL should be located exactly at f_{RF}_{_{—}}_{PLL}/N where f_{RF}_{_{—}}_{PLL} is the frequency of the multiphase RF PLL. Because of its narrow bandwidth and further process-voltage-temperature variations, a single LC tank based PLL cannot be used to cover the whole bandwidth of the wideband RF PLL. An approach to circumvent this problem is to use many slightly overlapping IF PLLs in parallel whose output signals will then be multiplexed to the reference signal input of the RF PLL. However, this approach is inefficient with respect to the available silicon area.

The design of a conventional analog PLL faces many problems that are related to the analog circuit design. For instance a typical problem is the mismatch between the PMOS and NMOS current sources in the charge pump. Another problem is related to the dead zone in the phase-frequency detector. All these problems degrade the phase noise performance of the PLL. Depending on the desired loop bandwidth the resulting size of the loop filter can become a problem, too.

A conventional analog PLL has many building blocks that are strongly dependent on the technology used to implement the PLL. An example is the type of capacitors used in the RC loop filter. Capacitor types with a high pF/μm²-number, e.g. thin-oxide caps, frequently have high leakage currents and need therefore to be replaced by a different capacitor type, e.g. thick-oxide dgncap (composed of a dual gate NFET transistor with a thick oxide layer), which is highly nonlinear because it is normally used for decoupling and not for loop filter caps. These examples illustrate how difficult it is when transferring an analog design from one technology to the other.

It is therefore a challenge to provide a phase-locked loop with a programmable division ratio while maintaining its speed. It is also a challenge to eliminate the analog loop filter. Another challenge is to reduce or eliminate source/sink current mismatch problems in the charge pump and dead zone problems in the phase-frequency detector. It is yet another challenge to reduce the technology dependency.

### SUMMARY OF THE INVENTION

The phase-locked loop according to the invention comprises a frequency acquisition loop. The frequency acquisition loop comprises a counter that is operable to count the number of periods of an oscillator signal occurring during a predetermined period of time that is derived from a reference signal period of a reference signal. The oscillator signal has an oscillator signal frequency and an oscillator signal phase. The frequency acquisition loop also comprises a subtractor that is operable to compare the counted number of periods with a desired division factor, wherein, and wherein f_{VCOlocked} denotes a desired frequency of the oscillator signal in a locked state of the phase-locked loop and f_{ref} denotes the frequency of said reference signal. The comparison results in a subtractor output frequency value. The phase-locked loop further comprises a phase acquisition loop. The phase acquisition loop comprises a phase rotator for adjusting the oscillator signal by a rotator phase, and a counter that is operable to count the number of periods of the phase-adjusted oscillator signal occurring during the predetermined period of time. The phase acquisition loop also comprises a subtractor that is operable to compare the counted number of periods with the desired division factor. The comparison results in a subtractor output phase value. The phase-locked loop further comprises a state machine that is operable to effectuate in dependence of the subtractor output frequency value and the subtractor output phase value an adjustment of the oscillator signal frequency and the oscillator signal phase.

With the phase-locked loop the following advantages are achievable: The division factor becomes variable while the speed can be maintained. Furthermore, silicon area can be reduced because no analog loop filter is required anymore. Thirdly, typical analog PLL problems, such as charge pump mismatch and dead zone problems, are reduced or even avoided. Fourthly, a higher reference frequency can be used to reduce the 20·log(N) contribution in the phase noise performance. Finally, the PLL design is better portable.

Advantageous further developments of the invention arise from the characteristics indicated in the dependent patent claims.

In a preferred embodiment of the phase-locked loop the phase acquisition loop is operable to jump back to the frequency acquisition loop, if the phase acquisition loop determines that the frequency locking has been lost. Hence the phase-locked loop can be adapted to reuse the frequency acquisition loop if it determines within the use of the phase acquisition loop that the frequency locking has been lost.

In a further preferred embodiment of the phase-locked loop the frequency acquisition loop is operable to adjust the frequency of the oscillator signal stepwise with a frequency step size which depends on the size of the difference between the counted periods and the desired value. With that a higher frequency resolution can be achieved. The frequency step size is also referred to as tuning voltage step. The frequency acquisition loop is hence operable to adjust the oscillator signal frequency of the oscillator signal stepwise with a tuning voltage step which depends on the size of the difference between the counted periods and the desired value.

In another preferred embodiment of the phase-locked loop the frequency acquisition loop comprises a phase rotator whose rotator phase is adjustable.

Over and above this, in another preferred embodiment of the phase-locked loop the phase acquisition loop can be operable to adjust the oscillator signal phase of the oscillator signal stepwise with an adjustable phase step.

In a further preferred embodiment the state machine determines the tuning voltage step, the adjustable phase, and/or the phase step by means of a look up table.

In yet a further preferred embodiment the phase-locked loop can comprise a voltage controlled oscillator for generating the oscillator signal, and a digital-analog converter which is arranged between the state machine and the voltage controlled oscillator. Alternatively thereto, the phase-locked loop can comprise a digital controlled oscillator for generating the oscillator signal.

Preferably, the counter of the phase-locked loop comprises a divider chain and latches, wherein the counter is reset after the predetermined period of time.

The phase-locked loop can be used in a serial data link.

### BRIEF DESCRIPTION OF THE DRAWINGS

The invention and its embodiments will be more fully appreciated by reference to the following detailed description of presently preferred but nonetheless illustrative embodiments in accordance with the present invention when taken in conjunction with the accompanying drawings.

The figures are illustrating:

FIG. 1 a block diagram of a phase-locked loop architecture,

FIG. 2 a timing diagram of the frequency acquisition loop,

FIG. 3 a timing diagram of the phase acquisition loop,

FIG. 4 a timing diagram with timing intervals and signal constellations being relevant when reading out the output values of the divider chain by the D-flip flops of the phase-locked loop,

FIG. 5 a flow diagram of a first embodiment of the frequency acquisition loop and the phase acquisition loop,

FIG. 6 a flow diagram of a second embodiment of the frequency acquisition loop and the phase acquisition loop,

FIG. 7 a flow diagram of a third embodiment of the frequency acquisition loop and the phase acquisition loop, and

FIG. 8 a block diagram of a serial data link comprising the phase-locked loop.

### DETAILED DESCRIPTION OF THE PREFERRED EMBODIMENT

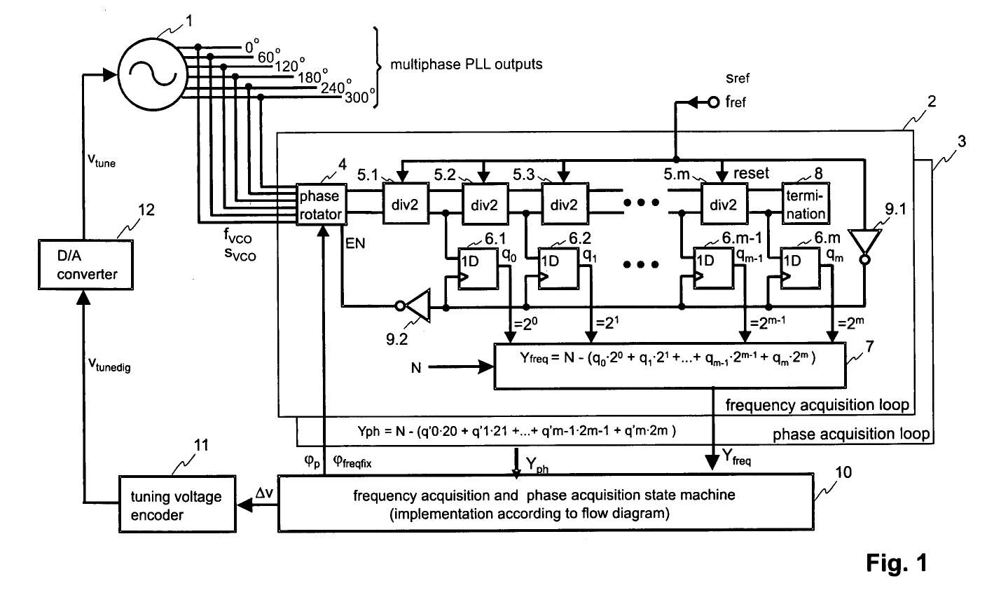

An embodiment of a phase-locked loop PLL is depicted in FIG. 1. The PLL has a multiphase ring oscillator 1 used as voltage-controlled oscillator (VCO). In the embodiment depicted in FIG. 1 the VCO 1 produces six VCO output signals s_{VCO}, also referred to as oscillator signals, with a common VCO output frequency f_{VCO}, corresponding oscillator signal periods T_{VCO} and six different phases (0°, 60°, 120°, 180°, 240°, 300°). The VCO output signals s_{VCO} are fed to a frequency acquisition loop 2 and a phase acquisition loop 3. To keep FIG. 1 simple only the components of the frequency acquisition loop 2 are shown, but both loops 2 and 3 comprise a phase rotator 4, a cascade of m divide-by-2 stages 5.1 to 5.m, m D-flip flops 6.1 to 6.m, and a subtractor 7. The difference in the implementation of these two loops 2, 3 is related to the amount of phase shifting introduced by the phase rotator 4. While the phase shift, i.e. rotator phase φₚ, of the phase rotator 4 in the frequency acquisition loop 2 remains unchanged or fixed and is referred to as φ_{freqfix}, the phase shift φₚ, i.e. rotator phase φₚ, of the phase rotator 4 in the phase acquisition loop 3 is varied. For instance, the rotator phase φₚ can be varied around the fixed rotator phase φ_{freqfix} within a reasonably wide range, e.g. 2π. Both phase rotator settings, φₚ and φ_{freqfix}, are adjusted and monitored, i.e. written and read, by a frequency acquisition and phase acquisition state machine 10. All m divide-by-2 stages 5.1 to 5.m together are hereinafter referred to as divider chain or counter because the divider chain works as counter. The D-flip flops 6.1 to 6.m are also referred to as latches. Each latch 6.1 to 6.m is connected with its input to the output of one of the divide-by-2 stages 5.1 to 5.m. In each loop 2, 3 the phase rotator 4 additionally has a control input referred to as output enable EN. At the end of the m divide-by-2 stages 5.1 to 5.m, also referred to as div-2 stages 5.1 to 5.m, a high-frequency termination 8 is provided which reduces or eliminates reflection in the conductor. A first inverter 9.1 and a second inverter 9.2 are connected in series and generate from a reference signal s_{ref} with a reference frequency f_{ref} and a corresponding reference signal period T_{ref} the output enable signal EN, which is passed to the control input of the phase rotator 4.

In another embodiment one phase rotator 4 can be provided for both, the frequency acquisition loop 2 and the phase acquisition loop 3, i.e. the phase rotator 4 is then a common part of both loops 2, 3. The output and the control inputs of the phase rotator 4 are then connected to the frequency acquisition loop 2, if the PLL is in a frequency acquisition mode, and connected to the phase acquisition loop 3, if the PLL is in a phase acquisition mode. Hence, the common phase rotator 4 assumes the fixed rotator phase φ_{freqfix} when the PLL is operated in the frequency acquisition loop 2 and the common phase rotator 4 assumes the adjustable rotator phase φₚ during phase acquisition.

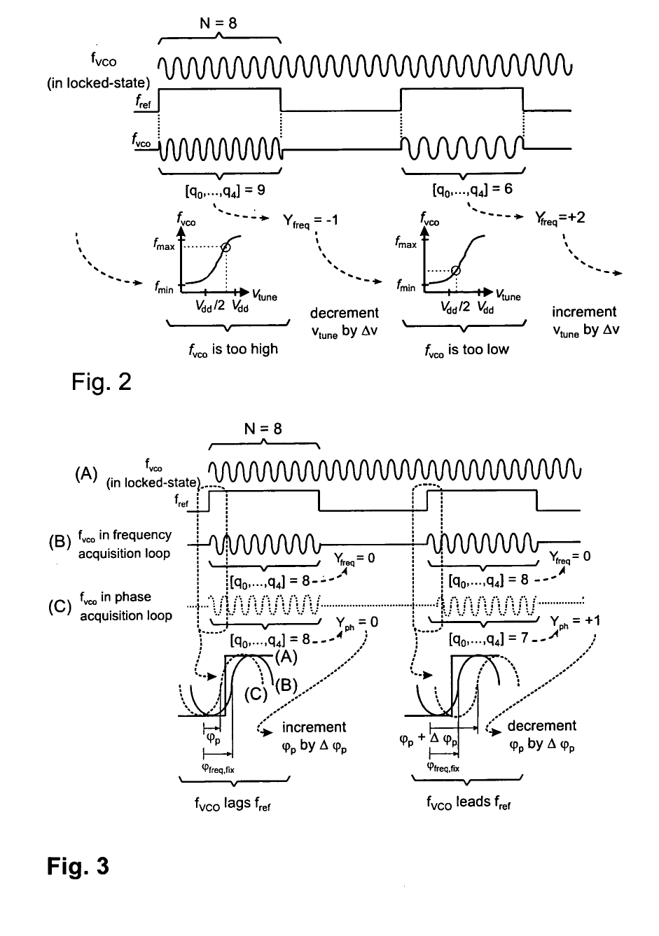

The loops 2, 3 work as follows: If the output of the phase rotator 4 is enabled by the output enable signal EN, the phase rotator 4 passes the VCO output signal s_{VCO} through during the high state of the reference signal s_{ref} (see FIG. 2). This means that the output signal of the phase rotator 4 is only fed to the divider chain 5.1 to 5.m during the positive half wave of the reference signal s_{ref}. The positive outputs of the div-2 stages 5.1 to 5.m are sensed by the D-flip flops 6.1 to 6.m, wherein the D-flip flops 6.1 to 6.m latch the states of the div-2 stages 5.1 to 5.m at a falling edge of the reference signal s_{ref}. The outputs q₀, q₁, . . . , qₘ−1, qₘ of the latches 6.1 to 6.m can be considered as the binary coded number q of the oscillator signal periods T_{VCO} within one half of the reference signal period (=0.5·T_{ref}), said binary number q being also referred to as divider chain value q. An example hereof is shown in FIG. 2. The counter 5.1-5.m, 6.1-6.m is hence operable to count the number q of periods T_{VCO} of the oscillator signal s_{VCO} occurring during the predetermined period of time ½ T_{ref}.

Once the outputs of the divider chain 5.1 to 5.m are latched, the following computations and activities are performed during the negative half period of the reference signal s_{ref}.

(1) The output of the phase rotator 4 gets disabled and the divider stages 5.1 to 5.m are reset so that the divider chain (counter) 5.1 to 5.m can resume counting from zero at the next rising edge of the reference signal s_{ref}.

It is not necessary that the reference signal s_{ref} is a signal with a duty cycle, i.e. a ratio of pulse length to cycle duration, of 50%. If the duration of the logical high state of the reference signal s_{ref} is longer than the duration of the logical low state, the counter 5.1 to 5.m can count longer, while the succeeding computations and activities are performed quicker, which increases the accuracy. The desired division factor N is modified correspondingly if the duty cycle of the reference signal s_{ref} deviates from 50%. For instance, if the duty cycle is 75%, the division factor is changed to 1.5×N in order to produce the same PLL output frequency as in the case where the duty cycle is 50% and the desired division factor is N.

(2) The latched divider chain value q=[q0, q1, . . . , qm−1, qm] is then fed to a subtractor 7 where the divider chain value q gets subtracted from a desired division factor N, where N is defined as:

wherein f_{VCOlocked} denotes a desired VCO output frequency in the locked state of the PLL. The desired division factor N can take any integer value. The subtractor output frequency value Y_{freq} of the subtractor 7 is:
Y_{freq}=N−(q₀·2⁰+q₁·2¹+q₂·2²+ . . . +qₘ·2^{m})

The resulting subtractor output frequency value Y_{freq} of the subtractor 7 is then analyzed in the state machine 10, also referred to as frequency acquisition and phase acquisition state machine, in the following way:
(a) First only the sign of the subtractor output frequency value Y_{freq} is analyzed. It can take three different values:
   (i) sgn(Y_{freq})<0: the VCO output frequency f_{VCO} is higher than the reference frequency f_{ref}. Therefore, the VCO output frequency must decrease for obtaining a frequency locking.
   (ii) sgn(Y_{freq})=0: the VCO output frequency f_{VCO} equals the reference frequency f_{ref}. This means that frequency locking is obtained.
   (iii) sgn(Y_{freq})>0: the VCO output frequency f_{VCO} is lower than the reference frequency f_{ref}. Therefore, the VCO output frequency must increase for obtaining a frequency locking.

The information about the sign of the subtractor output frequency value Y_{freq} is then passed over from the state machine 10 as a digital tuning voltage step Δv to a tuning voltage encoder 11. The tuning voltage encoder 11 increments or decrements the present valid digital value of the tuning voltage v_{tunedig} by means of the tuning voltage step Δv and passes the new digital value of the tuning voltage v_{tunedig} to a D/A converter 12. The D/A converter 12 then converts the new digital value of the tuning voltage v_{tunedig} to an analog tuning voltage vₜᵤₙₑ, which is then passed to the control input of the VCO 1.
(b) In addition to the evaluation of the sign of the subtractor output frequency value Y_{freq} the magnitude of the subtractor output frequency value Y_{freq} can also be evaluated in the state machine 10:
   |Y_{freq} |=abs(Y_{freq})=abs(N−(q₀2⁰+q₁·2¹+q₂·2²+ . . . +qₘ·2^{m}))

The magnitude of the subtractor output value Y_{freq} can be used to adjust the magnitude of the tuning voltage step Δv, i.e. the tuning voltage step Δv becomes adjustable.

An example of the frequency acquisition loop operation is illustrated in the timing diagram of FIG. 2. It is assumed that the divider chain 5.1 to 5.m has a length of m=4 and the desired division factor or ratio N is 8. During the first half period cycle of the reference signal s_{ref}, the output value q of the divider chain 5.1 to 5.m and the succeeding latches 6.1 to 6.m, also referred to as divider chain value q, is q=9 and therefore the subtractor output frequency value Y_{freq}=8−9=−1, which for frequency-locking requires a decrease of the tuning voltage vtune by the tuning voltage step Δv because the VCO output frequency f_{VCO} of the VCO 1 is higher than the reference frequency f_{ref}. After having decreased the tuning voltage vₜᵤₙₑ, the subtractor output frequency value Y_{freq} is evaluated again and now the subtractor output frequency value Y_{freq}=8−6=2 calls for incrementing the tuning voltage vₜᵤₙₑ again because the VCO output frequency f_{VCO} has become lower than the reference frequency f_{ref}. This procedure is repeated until the subtractor output frequency value Y_{freq}=0 is obtained.

Once frequency locking has been obtained, the PLL makes use of the phase acquisition loop 3. In the phase acquisition loop 3, the rotator phase φₚ of the phase rotator 4 is incremented until the oscillator signal phase φ_{VCO} of the VCO output signal s_{VCO} is aligned with the reference signal phase φ_{ref} of the reference signal s_{ref}. Once phase alignment has been obtained, the rotator phase φₚ of the phase rotator 4 is incremented and decremented by a phase step Δφ in an alternating fashion in order to center the oscillator signal phase φ_{VCO} of the VCO output signal s_{VCO} around the rising edge of the reference signal s_{ref}. The information on whether the rotator phase φₚ should be increased or decreased can be derived from the subtractor output phase value Yₚₕ, which corresponds to the output of the subtractor 7 in the phase acquisition loop 3. The subtractor 7 subtracts the binary coded value of the divider chain 5.1 to 5.m from the desired division factor N:
Yₚₕ=N−(q′₀·2⁰+q′₁·2¹+q′₂·2²+ . . . +q′ₘ·2^{m})
where q′=[q′₀, q′₁, . . . q′ₘ] is the output value of the latches 6.1 to 6.m of the phase acquisition loop 3. Hence, the output value q′ is the divider chain value q′ with the phase rotator 4 being subjected to the phase adjustment by the rotator phase φₚ in the phase acquisition loop 3.

The rotator phase φₚ of the phase rotator 4 is incremented until the subtractor output phase value Yₚₕ changes from 0 to 1, which means that the rising edge of the VCO output signal s_{VCO} is aligned with the rising edge of the reference signal s_{ref}, however, at a phase offset of ½ T_{VCO}. At that phase offset position the least significant counter value q′₀ does not toggle anymore from 0 to 1 or vice versa and therefore the binary coded value q′ of the divider outputs stored in the latches 6.1 to 6.m gets decreased by one, which in turns results for the subtractor output phase value Yₚₕ in a change from Yₚₕ=0 to Yₚₕ=1. Once this state is reached, the phase rotator 4 toggles the rotator phase φₚ around that phase offset position with phase increments, also referred to as phase steps, of +/−Δφ. This procedure continues until the PLL may loose frequency locking, which is when the PLL reuses the frequency acquisition loop 2 for frequency locking.

In a further embodiment of the PLL, the phase steps Δφ, i.e. the phase increments or decrements +/−Δφ of the rotator phase φₚ are adaptively adjusted to reduce the effect of noise produced by a too high value of the phase step Δφ. The adaptive adjustment is performed by evaluating the length of consecutive phase step changes from +Δφ to −Δφ or vice versa. Based on a look up table, the phase increments or decrements +/−Δφ for the phase rotator 4 are adaptively adjusted depending on the current pattern length of the changes of the phase steps Δφ.

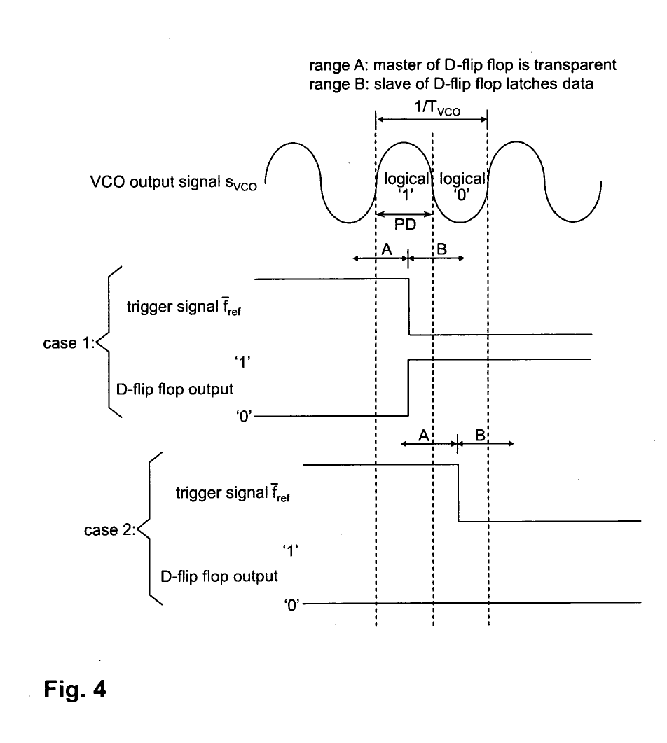

An example illustrating the functional principle of the phase acquisition loop 3 is given in the timing diagram of FIG. 3. In the following it is assumed that the phase rotator 4 has performed continuous phase increments Δφ so far but not as much as to achieve phase alignment. Therefore, the VCO output frequency f_{VCO} is still lagging the reference frequency f_{ref} and the subtractor output phase value Yₚₕ=0, or with other words, the VCO output signal is still lagging the reference signal s_{ref} by a phase difference. This situation is illustrated on the left hand part of FIG. 3. Because the subtractor output phase value Yₚₕ=0, the rotator phase φₚ gets incremented by the phase increment Δφ. However, after having applied the phase increment Δφ, the oscillator signal phase φ_{VCO} of the VCO output signal s_{VCO} leads the reference signal phase φ_{ref} of the reference signal s_{ref}. Because the phase increment Δφ is in this example as big as to shift the rotator phase φₚ beyond a critical phase offset where the least significant counter value of the divider chain value q′ does not toggle anymore in the divider chain 5.1 to 5.m, the subtractor output phase value Yₚₕ of the subtractor 7 yields Yₚₕ=+1, which causes the PLL to decrement the rotator phase φₚ again by the phase increment Δφ. Ideally, the phase increment Δφ is now continuously decreased by the step size adjustment method described above. FIG. 4 illustrates a potential frequency drift occurring in the frequency acquisition loop 2, which makes it recommendable to check for frequency locking even in the phase acquisition loop 3. During the period of time where the reference signal s_{ref} is high, the VCO output signal s_{VCO} propagates through the phase rotator 4 and the divider chain 5.1 to 5.m. Within that period of time the masters of the D-flip flops 6.1 to 6.m are transparent so that changes of the output of the div-2 stages 5.1 to 5.m are monitored by the D-flip flop's masters. That is, the D-flip flop's masters will follow the outputs of the div-2 stages 5.1 to 5.m but the D-flip flop's outputs do not change because the D-flip flop's slaves are in the ‘hold’ mode. If the reference signal s_{ref}—which is present at the clock input of the D-flip flops—changes from logical high to logical low, the slaves take over the current logical level of the masters and the masters get disabled. The slaves then hold the just read-in logical value until the next falling edge of the reference signal s_{ref}. The delay chain's reset signal that is also derived from the reference signal s_{ref} and the D-flip flop's falling edge clock should be delayed with respect to each other so that the D-flip flop's slaves can safely read the data from the D-flip flop's masters before the delay chain 5.1 to 5.m is reset.

If one assumes an infinitively high sensitivity of the D-flip flops, which means that the D-flip flop's master is able to detect a logical high level even if the input signal is only slightly higher than zero, it becomes clear that the D-flip flop's output assumes a logical high value if the falling edge of the reference signal s_{ref} occurs within the period of time indicated by the reference sign PD in FIG. 4. This means, that within the period of time PD the D-flip flop is able to detect a logical high. This implies that there is an uncertainty of one half of the VCO output signal period, i.e. ½ T_{VCO}, when detecting the VCO output frequency f_{VCO} with the proposed method based on comparing the counter value q with the predefined division factor N. If the desired division factor is N and the measured counter value is equal to N as well, the frequency acquisition loop 3 outputs Y_{freq}=N−N=0, which means that the PLL is frequency-locked. However, if the falling edge of the reference signal s_{ref} occurred near the beginning of the period of time PD shown in FIG. 4, then the VCO output frequency f_{VCO} might be slightly too high even though the counter value q is equal to the desired division factor N, and, vice versa, if the falling edge of the reference signal s_{ref} occurs near the ending of the period of time PD, the VCO output frequency f_{VCO} might be slightly too low. The difference between the actual VCO output frequency f_{VCO} and the ideal N·f_{ref} value manifests itself in a frequency drift, which may result in a loss of frequency locking in terms of the Y_{freq}=0 nomenclature. Since the PLL uses the phase acquisition loop 3 at the occurrence of Y_{freq}=0, it should be checked in the phase acquisition loop 3 whether the PLL is still frequency-locked or not. Such check should advantageously be done on a repetitive or continuous basis.

The cases 1 and 2 in FIG. 4 illustrate that the D-flip flop's output does not become logical one anymore, if the input signal of the divider chain 5.1 to 5.m in the frequency acquisition loop 2, which is referred to in FIG. 4 as the VCO output signal s_{VCO}, has been shifted too much with respect to the rising edge of the reference signal s_{ref} because the input signal is then already in the indicated logical zero region, which means that the counter value represented by [qₘ, qₘ₋₁, . . . , q₁, q₀] gets decreased by 1 because the least significant counter value q₀ that is the div2-stage 5.1 directly following the phase rotator 4, does not toggle anymore. The falling edges of the reference signal s_{ref} in case 1 and case 2 in FIG. 4 occur at the same point of time in a practical system because the reference frequency f_{ref} is assumed to be fixed and the VCO output frequency f_{vco} becomes phase shifted. The current signal configuration shown in FIG. 4, that implies a phase shift of the reference signal s_{ref}, has only been chosen for illustration purposes.

In a practical case, the PLL will initially go through a couple of iterations of the VCO output frequency f_{VCO} by means of the frequency acquisition loop 2 and use the phase acquisition loop 3 until the PLL is frequency-locked with no or only negligible frequency drift.

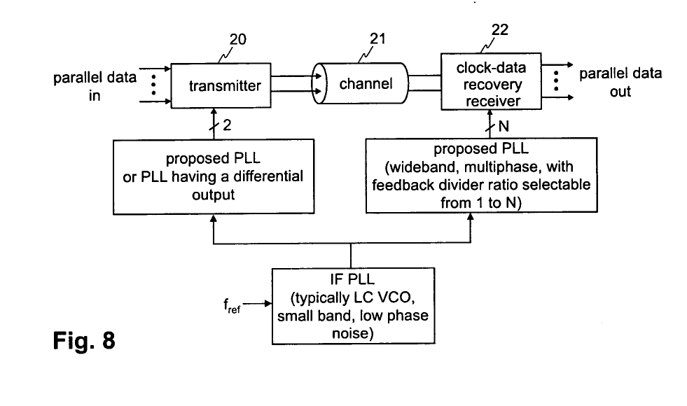

The PLL is also able to compensate relatively small frequency drifts in the phase acquisition loop 3 because it may eliminate relatively small displacements of the phase alignment location by appropriate changes of the phase settings in the phase rotator 4. That is, if the VCO output frequency f_{VCO} is slightly too high, then the relevant edge of the VCO output signal s_{VCO} used for the phase alignment will shift towards the right hand side with respect to the rising edge of the reference signal s_{ref}, which is assumed to remain unchanged with respect to the time axis. Since the phase rotator 4 in the phase acquisition loop 3 tries to align the rising edge of the reference signal s_{ref} with the relevant edge of the VCO output signal s_{VCO}, it will then constantly reduce its phase shift by the phase steps Δφ in order to compensate the increasing phase shift of the drifting VCO output signal s_{VCO}. In other words, if the PLL output signal is directly taken from the output of the phase rotator 4 in the phase acquisition loop 3, one gets a phase-locked signal even though the VCO output signal s_{VCO} is drifting. This configuration of the PLL might be used in applications where only a differential PLL output signal is used, e.g. at the transmitter of a serial link as depicted in FIG. 8. However, for those applications where all of the phase signals of the multiphase VCO oscillator signal s_{VCO} are used—which is typically the case at the receiver of a serial link in order to perform phase interpolation in the clock-data-recovery loop—one can take the original configuration where the PLL output comprises all the phase signals directly taken from the output of the VCO 1. In that configuration it takes longer until phase locking occurs because the PLL may first run through a number of frequency acquisition cycles in order to eliminate potential frequency drifts as described above.

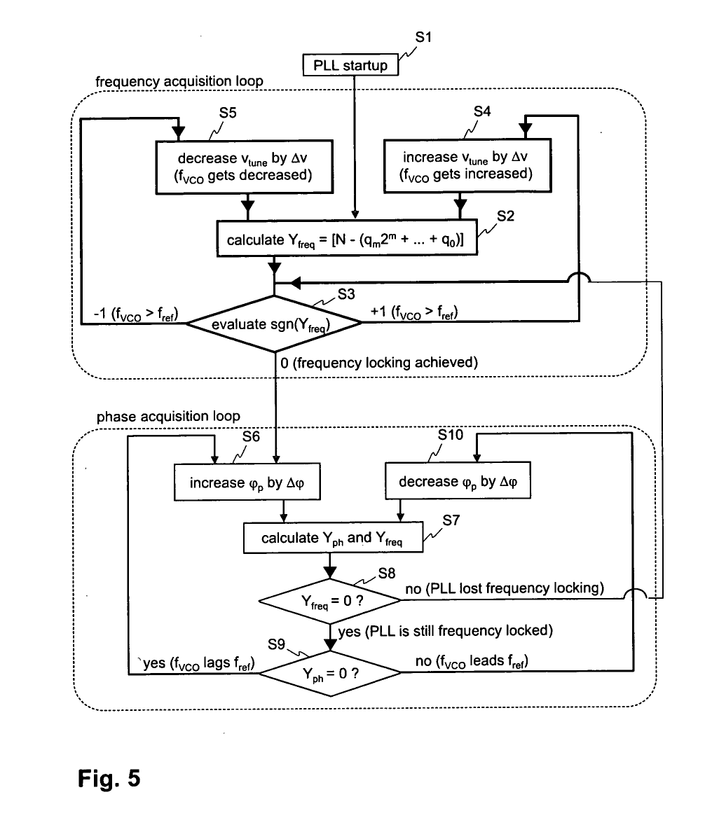

In the following the PLL flow chart as depicted in FIG. 5 is described, which is a first embodiment of the frequency acquisition loop 2 and phase acquisition loop 3. After the PLL has been started in a step S1, the frequency acquisition loop 2 is used in the following way. The divider chain 5.1 to 5.m is read by the D-flip flops 6.1 to 6.m, whose output values q₀ to qₘ represent the divider chain value q, i.e. the binary coded number q of cycles of the VCO output signal s_{VCO} within one half of the reference frequency period T_{ref}. That is, the number q of cycles of the VCO output signal s_{VCO} within 0.5·T_{ref} is:
q=qₘ·2^{m}+qₘ₋₁·2^{m-1}+ . . . +q₁·2+q₀

With that, in a step S2 the subtractor output frequency value Y_{freq} is calculated as:
Y_{freq}=N−(qₘ·2^{m}+qₘ₋₁·2^{m-1}+ . . . +q₁·+q₀)
wherein N is the desired division factor.

In a succeeding step S3 the sign of the subtractor output frequency value Y_{freq} is evaluated. If the sign of the subtractor output frequency value Y_{freq} is +1, then in a step S4 the tuning voltage vₜᵤₙₑ is increased by a tuning voltage step Δv, because the VCO output frequency f_{VCO} is too low. Afterwards the step S2 is repeated. If however the sign of the subtractor output frequency value Y_{freq} is −1, then the tuning voltage vₜᵤₙₑ is decreased in a step S5 by a tuning voltage step Δv, because the VCO output frequency f_{VCO} is too high. Afterwards the step S2 is repeated. It is assumed here that the VCO 1 has a positive tuning characteristic so that an increase of the tuning voltage vₜᵤₙₑ results in an increase of the VCO output frequency f_{VCO}. If the VCO characteristic is negative, the direction or the sign change correspondingly. If the sign of the subtractor output frequency value Y_{freq} is 0, then frequency locking has been achieved and the phase acquisition loop 3 is used next. The method is continued with a step S6. Frequency locking is achieved with an accuracy of:

$${f}_{ref} \pm \frac{1}{2 \cdot {T}_{VCO}}$$

At this point in the flow diagram the VCO output frequency f_{VCO} can still drift at a rate of maximal 1/T_{VCO}.

The phase acquisition works as follows: In the step S6, the rotator phase φₚ of the phase rotator 4 is increased in the phase acquisition loop 3 by a phase increment Δφ. Then, in a step S7 the subtractor output phase value Yₚₕ and the subtractor output frequency value Y_{freq} are calculated. The phase increment which has been applied in the step S6 is implicitly taken into account at the calculation of the subtractor output phase value Yₚₕ because the term q′ₘ·2^{m}+q′m−1·2^{m-1}+ . . . +q′₁·2+q′₀ determined in the phase acquisition loop 3 is affected by the actual value of rotator phase φp of the phase rotator 4. The single quote' behind the q-values indicates that the q-values are taken from the outputs of the D-flip flop 6.1 to 6.m of the phase acquisition loop 3. The corresponding outputs of the D-flip flops 6.1 to 6.m of the frequency acquisition loop 2 have no single quotes.

In a step S8 it is checked whether the PLL is still frequency-locked. If the subtractor output frequency value Y_{freq} equals 0, then the PLL is still frequency-locked and a step S9 is performed. If however the subtractor output frequency value Y_{freq} is unequal zero, then the step S3 is again executed. The PLL has then lost frequency locking because of the initially existing potential frequency drift pointed out at the step S3 or because of jitter or other noise effects.

In the step S9 it is checked whether the PLL is phase-locked. If the subtractor output phase value Yₚₕ equals zero, then in the step S6 the rotator phase φₚ is increased by the phase increment Δφ because the oscillator signal phase φ_{VCO} of the VCO output signal s_{VCO} lags the reference signal phase φ_{ref} of the reference signal s_{ref}. Afterwards the step S7 is performed again. If however the subtractor output phase value Yₚₕ is unequal to zero, such as Yₚₕ=1, then in a step S10 the rotator phase φₚ is decreased by the phase increment Δφ because the oscillator signal phase φ_{VCO} of the VCO output signal s_{VCO} leads the reference signal phase φ_{ref} of the reference signal s_{ref}. Afterwards, the step S7 is executed again.

The steps S6, S7, S8 and S9 represent an endless loop presumed that the PLL remains frequency-locked where the subtractor output phase value Yₚₕ repetitively toggles the subtractor output phase value Yₚₕ between Yₚₕ=0 and Yₚₕ=1. That is, the rotator phase φₚ gets constantly incremented and decremented by the phase increment Δφ and consequently a kind of “bang bang phase locking” is achieved.

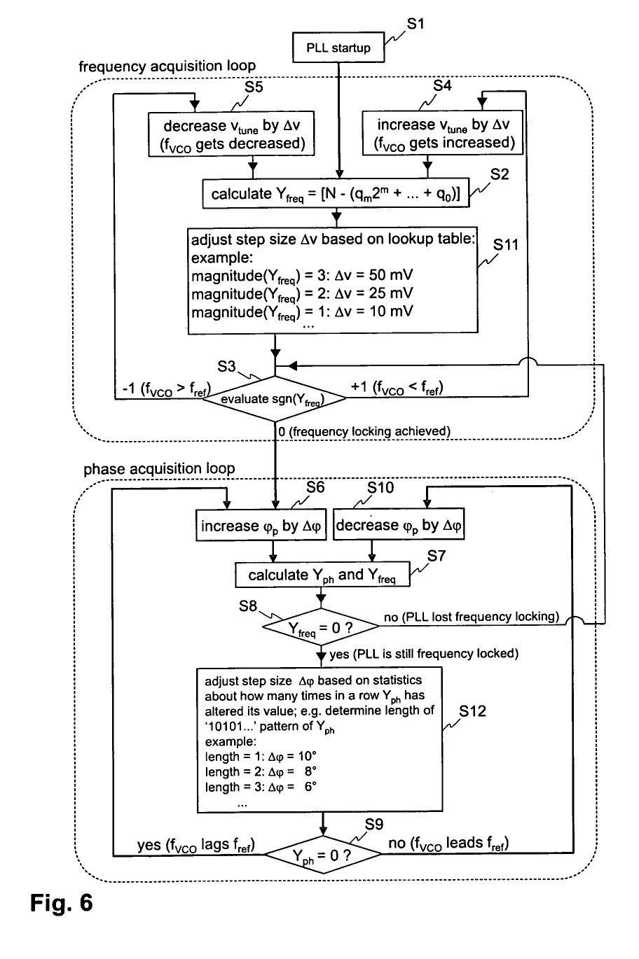

In the following the PLL flow chart as depicted in FIG. 6 is described, which is a second embodiment of the frequency and phase acquisition loops 2, 3. The flow chart shown in FIG. 6 represents an extension of the flow chart depicted in FIG. 5. The extension is related to the adjustment of the loop gain that is performed by adaptively adjusting the size of the tuning voltage step Δv in the frequency acquisition loop 2 and the phase increment Δφ in the phase acquisition loop 3. Both adjustments may improve the PLL's locking performance because the loop gain is adaptively reduced in the locked state, which also reduces the jitter generation of the PLL owing to introduced noise. The additional loop gain adjustment entities in the flow diagram of FIG. 6 can be described as follows. The adjustment of the tuning voltage step Δv in a step S11 works as follows: The adjustment of the tuning voltage step Δv is based on the evaluation of the magnitude of the subtractor output frequency value Y_{freq}. The larger the magnitude of the subtractor output frequency value Y_{freq} is, the larger the step size of the tuning voltage step Δv is that should be applied to obtain a faster frequency locking. Contrarily, with shrinking subtractor output value Y_{freq} the step size of the tuning voltage step Δv that is applied should be reduced in order to reduce the noise introduced by the locking method. These cases can be covered by means of a look up table where the magnitude of the subtractor output frequency value Y_{freq} is compared with a predetermined pattern of the settings for the size of the tuning voltage step Δv (see example in the step S11 of the flow chart of FIG. 6).

The adjustment of the phase increment Δφ in a step S12 works as follows: In the phase acquisition loop 3 the adjustable rotator phase φₚ of the phase rotator 4 aligns the oscillator signal phase φ_{VCO} of the VCO output signal s_{VCO} to the reference signal phase φ_{ref} of the reference signal s_{ref}. The phase acquisition in the steps S6, S7, S8, S9 and S10 as described above causes a toggling of the rising edge of the VCO output signal s_{VCO} around the rising edge of the reference signal s_{ref}. The falling edges of the reference signal s_{ref} could be used as well. In the flow chart shown in FIG. 5 the toggling is associated with a fixed value of the phase increment Δφ. Phase locking is indicated by a continuous change of the subtractor output phase value Yₚₕ from Yₚₕ=0 to Yₚₕ=1 and vice versa. This behavior represents the toggling of the edge of the VCO output signal s_{VCO} around the edge of the reference signal s_{ref} mentioned above. If the PLL starts toggling the value of the subtractor output phase value Yₚₕ, it makes then sense to reduce the fixed amount of the phase increment Δφ because this may help reduce the jitter generation caused by the introduced noise. This can be carried out by an evaluation of the number of changes of the subtractor output phase value Yₚₕ that have occurred in a row. Analogously to the adjustment of the tuning voltage step Δv, a look up table is used where the length of the events toggling the subtractor output phase value Yₚₕ is compared to predefined settings of the phase increment Δφ. As illustrated in the exemplary look up table in the step S12 of the flow diagram of FIG. 6, the rule applies that the longer the length of changes of the subtractor output phase value Yₚₕ is, the smaller the value of the phase increment Δφ becomes.

The phase acquisition loop 3 does in contrast to the frequency acquisition loop 2, not directly affect the VCO tuning voltage Vtune. What the phase acquisition loop 3 actually does is a repetitive adjustment of the phase rotator settings in the phase acquisition loop 3 in order to keep the VCO output signal s_{VCO} and the reference signal s_{ref} phase-aligned, even though a frequency drift of the VCO output signal s_{VCO} might exist compared to N*f_{ref}. This potential frequency drift gets compensated in the performance of the phase acquisition loop 3.

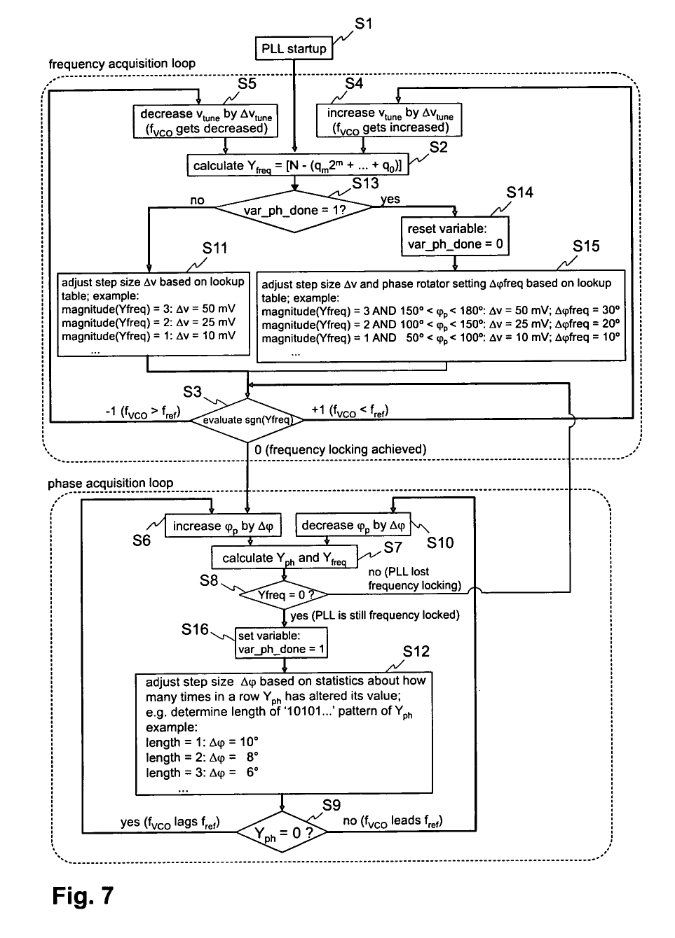

In a further configuration of the PLL an improved locking behavior is obtained by taking advantage of the current phase rotator setting in the phase acquisition loop 3 that will then be made available to the state machine 10. The flow diagram thereto is depicted in FIG. 7 and illustrates the PLL configuration used to accelerate the locking transient by exploiting the phase offset information given by φₚ−φ_{freqfix} in the frequency acquisition loop 2. Both phase shift values, φₚ and φ_{freqfix}, are available in the frequency acquisition and phase acquisition state machine 10 which might also determine the phase difference φₚ−φ_{freqfix}. Once the VCO output signal s_{VCO} has been aligned to the rising edge of the reference signal s_{ref}, the current phase rotator setting in the phase acquisition loop 3 gives an indication of how much the originally fixed phase rotator setting φ_{freqfix} in the frequency acquisition loop 2 is offset from the desired phase alignment location for the rotator phase φₚ determined in the phase acquisition loop 3. This information (φₚ−φ_{freqfix}) can then be used in the frequency acquisition loop 2 to either adjust its originally fixed phase rotator setting φ_{freqfix} to a new setting comparable to the just received phase rotator setting of the phase acquisition loop 3 or it might be used to adjust the tuning voltage steps Δv accordingly. The first approach may significantly accelerate the locking behavior. The second approach of adjusting the tuning voltage steps Δv accordingly may take more cycles of the reference signal s_{ref} until the PLL locks. The flow diagram of FIG. 7 illustrates a combination of both approaches. Based on a look up table approach, the phase rotator setting to the fixed rotator phase φ_{freqfix} and the tuning voltage steps Δv are adjusted in the frequency acquisition loop 2 according to the evaluation of the sign of the subtractor output frequency value Y_{freq}, the magnitude of the subtractor output value Y_{freq}, and the rotator phase φₚ of the phase rotator 4 in the phase acquisition loop 3. For sake of simplicity, in the look up table example of a step S15 shown in FIG. 7 only the rotator phase φₚ is used instead of the phase difference (φₚ−φ_{freqfix}) as input value. According to the flow diagram, the fixed phase rotator setting φ_{freqfix} is altered in the step S15 in phase rotator setting steps Δφ_{freq}. Compared to the previous flow charts of FIG. 5 and 6, a variable, referred to as phase alignment flag var_ph_done is introduced that indicates whether the phase acquisition loop 3 has already been passed and phase alignment was achieved. If the phase acquisition loop 3 has been passed and phase alignment was achieved, the phase alignment flag var_ph_done is set to 1 in a step S16. In the frequency acquisition loop 2 the phase alignment flag var_ph_done is checked in a step S13. If it is equal to zero the phase alignment flag var_ph_done is reset in a step S14 and the adjustment of the step size and phase rotator setting φ_{freqfix} is executed according to the step S15. Otherwise, the step S11, which has been already described above, is executed.

FIG. 8 illustrates the application of the proposed PLL in a serial link comprising a transmitter 20 accepting parallel data at its input, that are lateron serially transmitted via a data channel 21, and a clock-data recovery receiver 22 that outputs the recovered parallel data. The receiver 22 typically uses phase interpolators to generate the correct sampling phase for the detection of the received serialized data stream. Therefore, the PLL on the receiver side should provide multiple phases. A way to generate multiple phases is to use a ring-oscillator-based PLL. Ring oscillators have a relatively poor phase noise performance. In order to prevent that the ring PLL's phase noise performance is getting even worse when being directly connected to a noisy reference frequency source, a cascaded PLL concept can be used where the first PLL—the so called IF PLL—acts as clean-up PLL to make the reference frequency as clean as possible. This task uses a VCO 1 with a comparably low jitter generation, which typically results in using an LC oscillator in that PLL. However, the LC oscillator has a comparably narrow bandwidth. If the application intends to cover multiple frequency bands, the bandwidth of this PLL may not be able to track the wider bandwidth of the multiphase PLL. In order to solve this problem, the wideband PLL provides different feedback division factors in order to multiply the narrow-band IF PLL signal to the desired different datacom frequency bands of the serial link. The different division factors can be provided in the PLL by a so-called dual-modulus prescaler or Johnson divider. However at higher speeds a dual-modulus prescaler may have difficulties to operate appropriately because it uses an internal feedback loop to change from the division factor N to the division factor N+1. The PLL described in conjunction with FIGS. 1 to 7 solves this problem by using a fixed divided-by-2m divider comprising m divide-by-2 stages whose intermediate states are appropriately read and interpreted to obtain the different desired division factors.

Having illustrated and described a preferred embodiment for a novel method and apparatus for, it is noted that variations and modifications in the method and the apparatus can be made without departing from the spirit of the invention or the scope of the appended claims.

What is claimed is:

1. Phase-locked loop, comprising:
a frequency acquisition loop having
a counter operable to count the number of periods of an oscillator signal having an oscillator signal frequency and an oscillator signal phase occurring during a predetermined period of time, that is derived from a reference signal period of a reference signal and
a subtractor operable to compare the counted number of periods with a desired division factor, N, wherein, and wherein f_{VCOlocked} denotes a desired frequency of the oscillator signal in a locked state of the phase-locked loop and f_{ref} denotes the frequency of said reference signal, said comparison resulting in a subtractor output frequency value,
a phase acquisition loop having
a phase rotator for adjusting the oscillator signal by a rotator phase
a counter operable to count the number of periods of the phase-adjusted oscillator signal occurring during the predetermined period of time
a subtractor operable to compare the counted number of periods with the desired division factor, said comparison resulting in a subtractor output phase value,
a state machine operable to effectuate in dependence of the subtractor output frequency value and the subtractor output phase value an adjustment of the oscillator signal frequency and the oscillator signal phase of the oscillator signal.

2. Phase-locked loop according to claim 1, adapted to reuse the frequency acquisition loop, if it determines within the use of the phase acquisition loop that the frequency locking has been lost.

3. Phase-locked loop according to claim 1, wherein the frequency acquisition loop is operable to adjust the oscillator signal frequency of the oscillator signal stepwise with a tuning voltage step which depends on the size of the difference between the counted periods and the desired value.

4. Phase-locked loop according to claim 1, wherein the phase acquisition loop is operable to adjust the oscillator signal phase stepwise with an adjustable phase step.

5. Phase-locked loop according to one claim 1, wherein the state machine is adapted to determine the tuning voltage step, the rotator phase, and/or the phase step by means of a look up table.

6. Phase-locked loop according to claim 1, comprising a voltage controlled oscillator for generating the oscillator signal, and a digital-analog converter which is arranged between the state machine and the voltage controlled oscillator.

7. Phase-locked loop according to claim 1, wherein the counter comprises a divider chain and latches, and wherein the counter is reset after the predetermined period of time.
